(19) United States
(12) Patent Application Publication
(10) Pub. No.: US 2007/0277075 A1
(43) Pub. Date: Nov. 29, 2007

(54) Method of Generating Parity Information Using Low Density Parity Check

(76) Inventors: Ki-Hyun Kim, Seongnam-si (KR); Hyun-Jung Kim, Suwon-si (KR); Yoon-Woo Lee, Suwon-si (KR)

Correspondence Address: STEIN, MCEWEN & BUI, LLP, 1400 EYE STREET, NW, SUITE 300, WASHINGTON, DC, 20005, US

(21) Appl. No.: 10/580,911

(22) PCT Filed: Nov. 25, 2004
(86) PCT No.: PCT/KR04/03060

§ 371 Date: Mar. 29, 2007

(30) Foreign Application Priority Data
Nov. 28, 2003 (KR) 10-2003-0085770

(51) Int. Cl. H03M 13/00

(52) U.S. Cl. 714/752

(57) ABSTRACT

A method of independently generating row parity information and column parity information in an encoding process using a low density parity check (LDPC) matrix includes generating code word vectors by generating column parity information using a parity check matrix and message information; selecting code word bits for generating row parity information among code word bits in the generated code word vectors; and generating the row parity information using the selected code word bits, where the selecting of the code word bits comprises: excluding code word bits related to the generation of other row parity information. Accordingly, independent parity information can be generated by generating row parity information on the basis of code word bits without related to generation of column parity information.

### CROSS-REFERENCE TO RELATED APPLICATIONS

This application is a national phase of International Application No. PCT/KR2004/003060, filed Nov. 25, 2004, which claims the benefit of Korean Application No. 2003-85770, filed Nov. 28, 2003, in the Korean Intellectual Property Office, the disclosures of which are incorporated herein by reference.

### BACKGROUND OF THE INVENTION

1. Field of the Invention

Aspects of the present invention relate to a method of generating parity information, and more particularly, to a method of independently generating row parity information and column parity information in an encoding process using a low density parity check (LDPC) matrix.

2. Description of the Related Art

A low density parity check (LDPC) encoding and decoding method refers to an error correction encoding and decoding technology used in a wireless communication field and an optical recording/reproducing field. The LDPC encoding method was initially suggested by Gallager in 1962. However, since it was very difficult to manufacture a decoder at that time,

Each code word vector includes an x-bit message word x₁,x₂, . . . ,xₓ and p-bit parity information p₁,p₂, . . . ,pₚ. The parity information p₁,p₂, . . . ,pₚ is generated so that the message word x₁,x₂, . . . ,xₓ satisfies Equation 1. That is, since a binary value of the message word to be coded among components of the parity check matrix H and matrix Cₑ is determined, parity information pᵢ (i=1, 2, . . . , p) can be determined using Equation 1. A more detailed description of the LDPC encoding process is described in the article “Good Error Correction Codes Based on Very Sparse Matrices” (D. J. MacKay, IEEE Trans. on Information Theory, vol. 45, no. 2, pp. 399-431, 1999).

In the LDPC encoding process, parity information is generated in every code word vector. That is, row parity information for decoding is generated. In a general block encoding process, the generation of column parity information is required for obtaining an excellent decoding performance. In a representative block encoding method, such as the Reed-Solomon encoding method, column and row parity information are generated.

FIG. 1 illustrates a concept of generating row parity information in an LDPC encoding process. Referring to FIG. 1, A, B, C, D, . . . indicate code word vectors, respectively. a₁, a₂, b₁, b₂, . . . indicate message word bits included in the respective code word vectors A, B, C, D, . . . P_{A}, P_{B}, P_{C}, . . . indicate column parity information generated in the respective code word vectors A, B, C, D, . . . P1 . . . indicates row parity information generated for message word bits in rows across the respective code word vectors.

the LDPC encoding method has been abandoned. Recently, the LDPC encoding method has been reproposed by Mackey.

The LDPC encoding method includes a process of generating parity information using a parity check matrix. Generally, most components of the parity check matrix are 0, and very sparse components of the parity check matrix are 1. The LDPC encoding method has an excellent error correction performance due to the method repeatedly performing an encoding process using an adding/multiplying algorithm. For example, an irregular LDPC encoding process where the length of encoding language is 10⁶ and an encoding rate is ½ has a performance closer to the Shannon limit, which is better than that of a turbo encoding process.

The LDPC encoding process is divided into a regular LDPC encoding process and an irregular LDPC encoding process. In the regular LDPC encoding process, the number of 1s included in a parity check matrix used for encoding and decoding is the same in every row and in every column. Otherwise, the LDPC encoding process is irregular.

The LDPC encoding process can be represented as shown in Equation 1.
H×Cₑ=0 Equation 1
where, H indicates a parity check matrix, 0 indicates a zero matrix, “x” indicates an XOR operation and a modular 2 operation, and Cₑ indicates a code word matrix which includes a number of code word vectors.

In a general block encoding process used for an optical disc system such as a DVD, one block size is 32 through 64 Kbytes. On the other hand, since a length of a general code word vector used for an LDPC encoding process is about 1 Kbyte, the number of columns in a block used for the LDPC encoding process is 32 through 64. When row parity information is generated, it is not efficient in the side of an error correction performance using the parity information to generate the parity information for only 32 through 64 bits. Therefore, when the row parity information is generated in the LDPC encoding process, the row parity information is generally generated by dealing with a plurality of rows together. FIG. 1 illustrates that a row encoding process of 4 code word vectors is performed by dealing with 2 rows together with a common row parity P1.

However, since the row encoding method sequentially extracts code word bits existing in code word vectors to be row encoded from a top position, errors are generated due to a correlation existing in the LDPC encoding process. Accordingly, it is impossible to generate independent parity information. That is, according to a method of selecting objects of the row parity information in one code word vector, row parity information may have a correlation with column parity information, and in this case, when an error is generated in the column parity information, an error is also generated in the row parity information. Accordingly, the reliability of the row parity information is reduced.

### SUMMARY OF THE INVENTION

Aspects of the present invention provide a method of generating row parity information without any correlation with generation of column parity information in an encoding process using a low density parity check (LDPC) matrix.

According to an aspect of the invention, by using a method of generating row parity information without any correlation with generation of column parity information in an encoding process using a low density parity check (LDPC) matrix, errors generated in the column parity information do not influence the row parity information.

According to an aspect of the present invention, there is provided an encoding method using a low density parity check (LDPC) matrix, the method comprising: generating code word vectors by generating column parity information using a parity check matrix and message information; selecting code word bits for generating row parity information among code word bits in the generated code word vectors; and generating the row parity information using the selected code word bits, wherein the selecting code word bits comprise: excluding code word bits related to the generation of other row parity information.

According to another aspect of the present invention, there is provided a method of selecting code word bits used for generating parity information in an information generating operation using an LDPC matrix, the method comprising: selecting a first code word bit; and selecting a second code word bit among residual code word bits except code word bits having a correlation with the first code word bit, wherein if the first code word bit is related to the generation of row parity information, and if, in a row number where a component corresponding to the first code word bit in the parity check matrix is 1, a component corresponding to the second code word bit in the row of the parity check matrix is 1, there is a correlation between the first and second code word bits.

Additional aspects and/or advantages of the invention will be set forth in part in the description which follows and, in part, will be obvious from the description, or may be learned by practice of the invention.

### BRIEF DESCRIPTION OF THE DRAWINGS

The above and other features and/or advantages of the present invention will become more apparent and more readily appreciated by describing in detail exemplary embodiments thereof with reference to the accompanying drawings in which:

FIG. 1 illustrates generation of row parity information in an LDPC encoding process;

FIG. 2 is a flowchart of an LDPC encoding method according to an embodiment of the present invention;

FIG. 3 illustrates an arrangement of code word bits selected for generating row parity information in the LDPC encoding method according to an embodiment of the present invention;

FIG. 4 illustrates an example correlation between a structure of a parity check matrix and code word bits;

FIG. 5 is an example factor graph representing the parity check matrix of FIG. 4;

FIG. 6 illustrates a method of selecting correlated code word bits using a factor graph according to an aspect of the invention;

FIG. 7 illustrates a method of selecting a succeeding selectable code word bit when code word bit “3” is selected as a second code word bit in FIG. 6 according to an aspect of the invention;

FIGS. 8 through 10 illustrates procedures of selecting residual code word bits when code word bit “2” is selected as a first code word bit in the parity check matrix of FIG. 4 according to an aspect of the invention; and

FIG. 11 is a flowchart of a method of selecting code word bits for generating row parity information using a factor graph according to an aspect of the invention.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

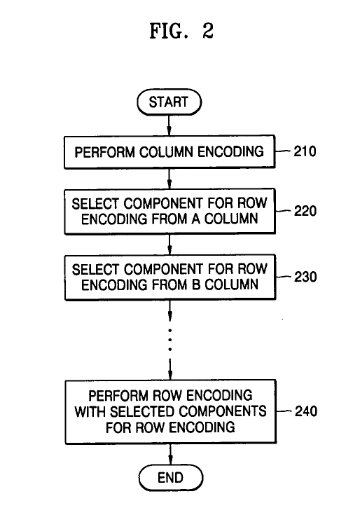

FIG. 2 is a flowchart of an LDPC encoding method according to an embodiment of the present invention. When message word bits are defined, code word vectors A, B, C, . . . are generated by generating column parity information on the basis of Equation 1 described above. The column parity information is generated in a column encoding process (operation 210). Code word bits to perform a row encoding process with respect to a code word vector are selected (operation 220). In the shown embodiment, the selected code word bits do not have a correlation with a parity check matrix H. Code word bits to perform the row encoding process with respect to each of the other code word vectors are selected (operation 230). The row encoding process is performed by generating as many row parity information as the number of rows according to a predetermined block size on the basis of the selected code word bits (operation 240).

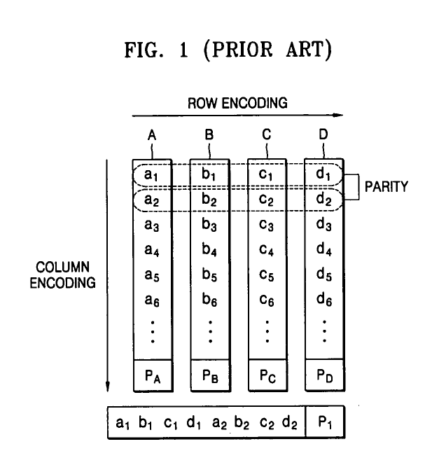

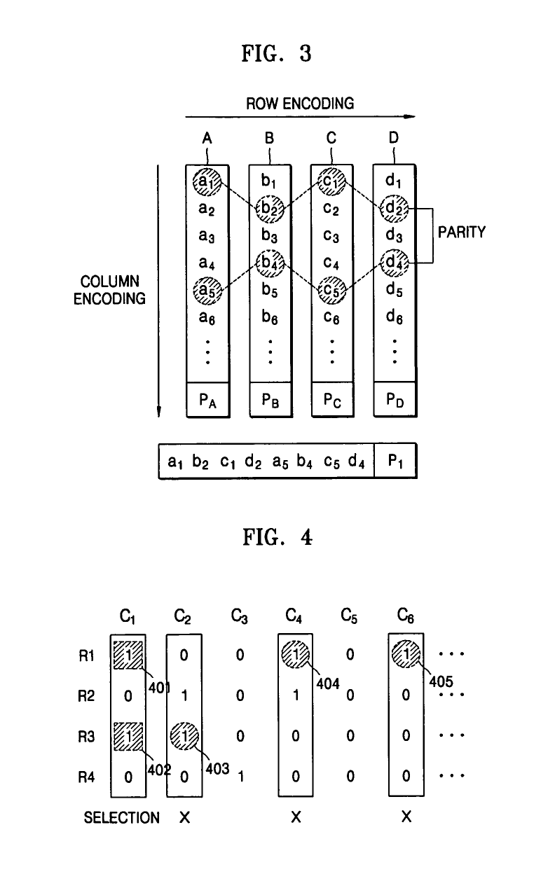

FIG. 3 illustrates an arrangement of code word bits selected for generating row parity information in the LDPC encoding method according to an embodiment of the present invention. Referring to FIG. 3, code word vectors A, B, C, and D have code word bits a₁, a₂, a₃, . . . , b₁, b₂, b₃, . . . , respectively. Unlike the conventional method of FIG. 1, the code word bits selected by a row encoding method according to an aspect of the present invention are not sequentially selected in the respective code word vectors. The code word bits a₁ and a₅ selected in the code word vector A are not correlated with each other. An aspect of the present invention provides a method of selecting the non-correlated code word bits by selecting a certain code word bit and removing code word bits correlated with the certain code word bit.

FIG. 4 illustrates a correlation between a structure of a parity check matrix H and code word bits. When a binary value change of each code word bit in a code word vector causes a change in the same row parity information, the code word bits are correlated with each other. A method of seeking code word bits correlated with a specific code word bit from a structure of a parity check matrix will now be described.

Column parity information P_{A}, P_{B}, . . . is generated using Equation 1 so that a result of multiplying (XOR operation and modular 2 operation) a parity check matrix H by respective code word vectors A, B, C, and D is a zero matrix. To generate the column parity information P_{A}, elements influencing the column parity information P_{A} in the parity check matrix H are all 1s existing in the parity check matrix H. However, when the column parity information P_{A} is generated, components including a specific component (for example, a₁) of the code word vector A influence the generation of the column parity information P_{A} only when a component hⱼₖ of the parity check matrix H multiplied by each component of the code word vector A is 1. It is shown in Equation 2.
mod 2[h₁₁a₁+h₁₂a₂+ . . . h₁ₙan+h₁ₙ₊₁P_{1A}+h₁ₙ₊₂P_{2A}+ . . . ]=z₁
mod 2[h₂₁b₁+h₂₂b₂+ . . . h₂ₙbn+h₂ₙ₊₁P_{1B}+h₂ₙ₊₂P_{2B}+ . . . ]=z₂ Equation 2
where, hⱼₖ indicates jth row −kth column components of the parity check matrix H, a₁, a₂, . . . are components of the code word vector A, P_{1A}, P_{2A}, . . . are column parity information generated with respect to the code word vector A, and n represents a number of rows. Therefore, when a component of the parity check matrix H corresponding to a specific code word bit (a₁ in FIG. 3 and components 401, 402 of FIG. 4) is 1, if components 403, 404, and 405 in FIG. 4 of the parity check matrix H corresponding to other code word bits to be multiplied are 1, the other code word bits are correlated with the specific code word bit. That is, code word bits corresponding to locations where components in the same rows of the parity check matrix H are 1 are correlated with each other.

If it is assumed that the specific code word bit is a₁ in the parity check matrix H of FIG. 4, components 401 and 402 corresponding to a₁ in the parity check matrix H are 1. In a case of the component 401 (that is, when the code word bit a₁ is multiplied by 1 in the first row and first column of the parity check matrix), components 404 and 405 are placed on locations where components in the row of the parity check matrix including the component 401 are 1. Therefore, code word bits a₄ and a₆ corresponding to the components 404 and 405 are correlated with the code word bit a₁.

In a case of the component 402 (that is, when the code word bit a₁ is multiplied by 1 in the third row and first column of the parity check matrix H), a component 403 is placed on a location where a component in the row of the parity check matrix including the component 402 is 1. Therefore, a code word bit a₂ corresponding to the component 403 is correlated with the code word bit a₁. Accordingly, code word bits correlated with a₁ are a₂, a₄, and a₆. That is, code word bits a₁, a₂, a₄, and a₆ influence the generation of the column parity information P_{A} together.

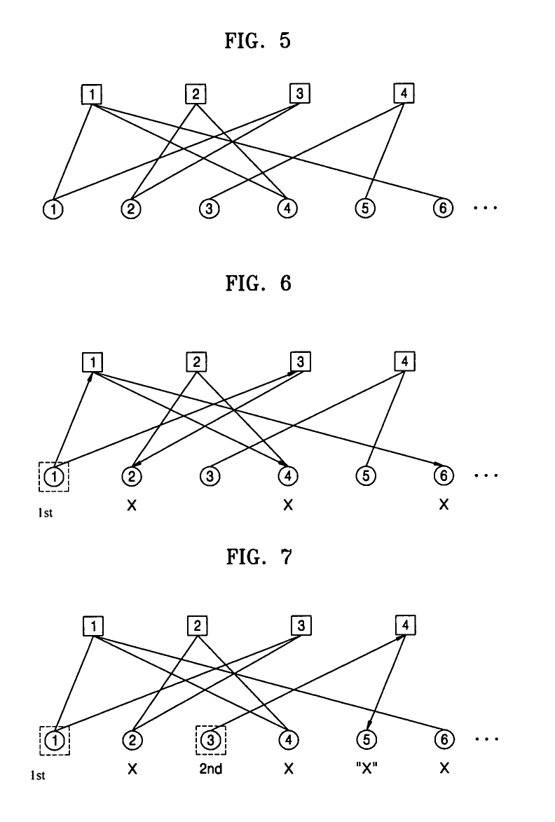

These correlated code word bits can be more easily discovered using a factor graph, such as the factor graph of FIG. 5. FIG. 5 is an example of a factor graph representing the parity check matrix H of FIG. 4. A factor graph specifies a parity check matrix H. The factor graph is made up of row nodes, column nodes, and connection lines. In FIG. 5, rectangular nodes (upper 4 nodes) indicate the row nodes, round nodes (lower 6 nodes) indicate the column nodes, and lines connecting the row nodes and the column nodes indicate the connection lines. The row nodes indicate rows of the parity check matrix H, and the column nodes indicate columns of the parity check matrix H. When components in locations where the rows and the columns are crossed are 1, the relevant rows and columns are connected to each other by the connection lines. Since a component of the row “1”-column “1” of the parity check matrix in FIG. 4 is 1, row node “1” and column node “1” are connected through the connection line in the factor graph of FIG. 5.

FIG. 6 illustrates an example of how to implement a method of selecting correlated code word bits using a factor graph. A factor graph is used for looking for correlated components in a parity check matrix H. All column nodes connected to each other are correlated in the factor graph. In FIG. 6, column node “1” is connected to column nodes “4” and “6” via row node “1”. Also, the column node “1” is connected to column node “2” via row node “3”. Column nodes “3” and “5” are not connected to the column node “1”. Accordingly, the column nodes “2”, “4”, and “6” are correlated with the column node “1”.

The number of column nodes in the factor graph indicates the number of code word bits. That is, the column nodes build one row in the parity check matrix H by being arranged horizontally, and each component of the row are multiplied by each code word bit in order to generate column parity information. Accordingly, code word bits having the same number as correlated column nodes are correlated with each other.

FIG. 6 shows that the column node “1” is selected as a first code word bit for generating parity information. As described above, correlated column nodes can be selected using a connection line relationship. First, the column node “1” is connected to column nodes “4” and “6” via a row node “1”. Therefore, the column nodes “1”, “4”, and “6” are correlated with each other. Also, the column node “1” is connected to a column node “2” via a row node “3”. Therefore, column nodes “1” and “2” are correlated with each other. Putting them together, the column nodes “1”, “2”, “4”, and “6” are correlated with each other. In other words, the code word bits “1”, “2”, “4”, and “6” are correlated with each other. Therefore, if the code word bit “1” is selected for generating the row parity information, it is preferable that the code word bits “2”, “4”, and “6” not be selected for generating the same parity information P_{A}. That is, in the shown example, only the code word bits “3” and “5” can be selected for generating the same parity information P_{A}.

FIG. 7 illustrates an example of how to implement a method of selecting a succeeding selectable code word bit when the code word bit “3” is selected as a second code word bit in FIG. 6. Since the code word bit “3” was selected for generating the parity information P_{A}, code word bits correlated with the code word bit “3” cannot be selected as a code word bit for generating the parity information P_{A} any more. Referring to FIG. 7, the column node “3” is connected to column node “5” via row node “4”. Therefore, in the shown example, when a third code word bit is selected, the column node “5” must be excluded.

If the column node “5” is selected as the second code word bit, the code word bit “3” will be excluded since the code word bit “3” is connected to the column node “5” via the row node “4”. From a fourth code word bit, after unselectable code word bits are excluded using the same method as described above, each code word bit is selected among the residual code word bits.

To generate the same row parity information, the number of code word bits that must be selected in a code word vector depends on a block size, the number of code word vectors to be used for generating row parity information, and the length of code word vector. If the size of error correction block is 32 Kbytes as occurs in an optical system such as a DVD, the length of code word vector is 1 Kbytes, and the number of code word vectors used for generating row parity information is 16, the number of code word bits to be selected for generating parity information in a code word vector is 32/(1*16)=2.

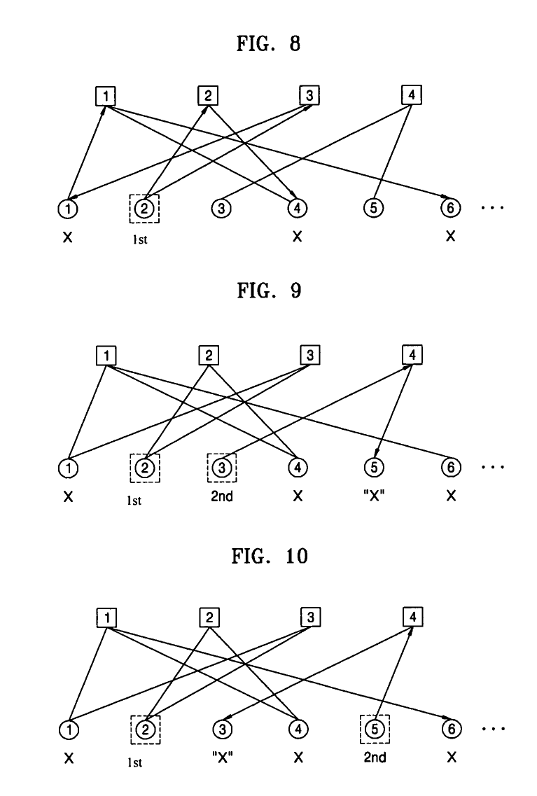

FIGS. 8 through 10 illustrate an example of procedures of selecting residual code word bits when code word bit “2” is selected as a first code word bit in the parity check matrix of FIG. 4. In FIG. 8, since code word bit “2” was selected as a first code word bit, code word bits “1”, “4”, and “6” cannot be selected as a second code word bit. Also, if code word bit “3” is selected as the second code word bit as shown in FIG. 9, code word bit “5” cannot be selected as a third code word bit. If the code word bit “5” is selected as the second code word bit as shown in FIG. 10, the code word bit “3” cannot be selected as the third code word bit. Therefore, a selectable code word depends on previously selected code word bits.

In an aspect of the present invention, a first selection group, a second selection group, and additional selection group are defined as selection groups for selecting corresponding row code word bits. That is, the first selection group is a set of code word bits that can be selected as the second code word bit determined by selecting the first code word bit, the second selection group is a set of code word bits that can be selected as the third code word bit determined by selecting the second code word bit, and so on.

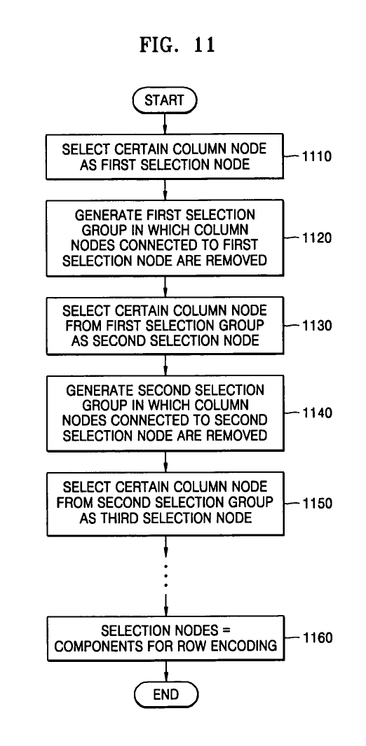

FIG. 11 is a flowchart of a method of selecting code word bits for generating row parity information using a factor graph. If a code word vector is determined by generating column parity information, a certain code word bit in the code word vector is selected as a first code word bit. That is, a certain column node in a factor graph is selected as a first selection node (operation 1110). A first selection group including only residual nodes except all column nodes connected to the first selection node is generated by checking a structural connection relationship of a factor graph (operation 1120). As shown, the all column nodes connected to the selection node include all column nodes connected to the selection node via certain row nodes.

A certain column node is selected as a second selection node from the first selection group (operation 1130). Like operation 1120, a second selection group including only residual nodes except all column nodes connected to the second selection node is generated (operation 1140). Until all selection nodes are determined, operations 1130 and 1140 are repeated from operation 1150. If all selection nodes are determined, code word bits corresponding to the selection nodes become code word bits for generating single row parity information in a code word vector (operation 1160). By repeating operations 1110 through 1160 in a second code word vector, code word bits are selected and also used for generating the single row parity information.

As described above, by using a method of generating row parity information without any correlation with generation of column parity information in an encoding process using a low density parity check (LDPC) matrix, errors generated in the column parity information do not influence the row parity information. According to aspects of the invention, the encoding process is usable in an encoder/decoder used in transferring data with respect to media (such as optical media) and/or for data transmission (such as wireless communication).

While aspects of this invention has been particularly shown and described with reference to specific embodiments thereof, it will be understood by those skilled in the art that various changes in form and details may be made therein without departing from the spirit and scope of the invention as defined by the appended claims. The described embodiments should be considered in descriptive sense only and not for purposes of limitation. Therefore, the scope of the invention is defined not by the detailed description of the invention but by the appended claims, and all differences within the scope will be construed as being included in the present invention.

1. An encoding method using a low density parity check (LDPC) matrix, the method comprising:
generating code word vectors by generating column parity information using a parity check matrix and message information;
selecting code word bits for generating row parity information using code word bits not including other code word bits related to generation of same row parity information among code word bits in the generated code word vectors; and
generating the row parity information using the selected code word bits.

2. The method of claim 1, wherein the selecting of the code word bits is performed on the basis of locations where components of the parity check matrix are 1.

3. The method of claim 1, wherein:
a first code word bit is related to the generation of the row parity information, a row number where a component corresponding to the first code word bit in the parity check matrix is 1,
a component corresponding to a second code word bit in the row of the parity check matrix is 1, and
the selecting includes selecting a certain code word bit among residual code word bits and not selecting the second code word bit as a code word bit for generating the row parity information.

4. The method of claim 1, wherein
the selecting of the code word bits comprises:
selecting a certain code word bit of the code word vector as a first selection code word bit;
generating a first selection group including residual code word bits other than code word bits correlated with the first selection code word bit in the code word vector; and
selecting another certain code word bit among code word bits of the first selection group as a second selection code word bit and which is not correlated to the first selection code word bit, and
there is a correlation between the first and second selection code word bits when the first selection code word bit is related to the generation of row parity information, a row number where a component corresponding to the first selection code word bit in the parity check matrix is 1, and a component corresponding to the second selection code word bit in the row of the parity check matrix is 1.

5. The method of claim 1, wherein the selecting of the code word bits is performed on the basis of a factor graph of the parity check matrix.

6. The method of claim 5, wherein the selecting of the code word bits comprises:
generating the factor graph of the parity check matrix;
extracting code word bits for generating the same column parity information on the basis of a connection relationship between column nodes included in the factor graph; and
selecting a certain code word bit among residual code word bits except the code word bits for generating the same column parity information as a code word bit for generating row parity information.

7. The method of claim 6, wherein the generating of the factor graph comprises:
arranging row and column nodes corresponding to row and column numbers of the parity check matrix, respectively; and
where components in locations corresponding to the row and column numbers of the parity check matrix are 1, connecting the row and column nodes with connection lines.

8. The method of claim 6, wherein the extracting of the code word bits comprises:
selecting a certain code word bit in the code word vector as the first selection code word bit;
extracting a first column node corresponding to the first selection code word bit from the factor graph;
extracting a certain second column node among residual column nodes except all column nodes connected to the first column node via connection lines; and
selecting a code word bit corresponding to the second column node as the second selection code word bit.

9. The method of claim 8, wherein the column nodes connected to the first column node via connection lines comprises all column nodes connected to the first column node via certain row nodes.

10. A method of selecting code word bits used for generating parity information in an information generating operation using an low density parity check (LDPC) matrix, the method comprising:
selecting a first code word bit; and
selecting a second code word bit among residual code word bits not including code word bits having a correlation with the first code word bit,
wherein the correlation exists between the first and second code word bits when the first code word bit is related to the generation of row parity information, a row number where a component corresponding to the first code word bit in the parity check matrix is 1, and a component corresponding to the second code word bit in the row of the parity check matrix is 1.

11. The method of claim 10, wherein the correlation is achieved when a column node corresponding to the first code word bit is connected to a column node corresponding to the second code word bit in a factor graph of the parity check matrix.

12. The method of claim 11, wherein the correlation is achieved when the column node corresponding to the second code word bit is connected to the column node corresponding to the first code word bit via a certain row node in the factor graph of the parity check matrix.

13. A method of optically transferring data, the method comprising transferring data with respect to an optical medium using a low density parity check (LDPC) matrix, wherein the data on the optical recording medium is encoded using generated row parity information of the LDPC matrix is generated by generating code word vectors by generating column parity information using a parity check matrix and message information; selecting code word bits for generating row parity information using code word bits not including other code word bits related to generation of same row parity information among code word bits in the generated code word vectors; and generating the row parity information using the selected code word bits.

14. The method of claim 13, wherein the transferring comprising:
encoding data using the generated row parity information of the LDPC matrix; and
recording the encoded data on the optical medium.

15. The method of claim 13, wherein the transferring comprising:
reproducing the encoded data from the optical medium; and
decoding the read encoded data according to the generated row parity information of the LDPC matrix.

16. A method of wirelessly transferring data, the method comprising transferring data using a low density parity check (LDPC) matrix, wherein the data is encoded using generated row parity information of the LDPC matrix is generated by generating code word vectors by generating column parity information using a parity check matrix and message information; selecting code word bits for generating row parity information using code word bits not including other code word bits related to generation of same row parity information among code word bits in the generated code word vectors; and generating the row parity information using the selected code word bits.

17. The method of claim 16, wherein the transferring comprising:
encoding data using the generated row parity information of the LDPC matrix; and
wirelessly transmitting the encoded data.

18. The method of claim 16, wherein the transferring comprising:
wirelessly receiving the encoded data; and
decoding the received encoded data according to the generated row parity information of the LDPC matrix.

19. The method of claim 16, wherein:
the selecting of the code word bits comprises:
selecting a certain code word bit of the code word vector as a first selection code word bit;
generating a first selection group including residual code word bits other than code word bits correlated with the first selection code word bit in the code word vector; and
selecting another certain code word bit among code word bits of the first selection group as a second selection code word bit, and
there is a correlation between the first and second selection code word bits when the first selection code word bit is related to the generation of row parity information, a row number where a component corresponding to the first selection code word bit in the parity check matrix is not zero, and a component corresponding to the second selection code word bit in the row of the parity check matrix is not zero.

20. An optical system including a decoder to decode data according to the method of claim 15.
